(19) United States
(12) Patent Application Publication
(10) Pub. No.: US 2014/0313426 A1
(43) Pub. Date: Oct. 23, 2014

(54) TELEVISION RECEIVER AND ELECTRONIC DEVICE

(71) Applicant: KABUSHIKI KAISHA TOSHIBA, Tokyo (JP)

(72) Inventor: Yuki Sato, Tokyo (JP)

(73) Assignee: KABUSHIKI KAISHA TOSHIBA, Tokyo (JP)

(21) Appl. No.: 14/059,197

(22) Filed: Oct. 21, 2013

(30) Foreign Application Priority Data
Apr. 23, 2013 (JP) 2013-090682

(51) Int. Cl. H04N 5/64; H05K 5/02

(52) U.S. Cl. CPC H04N 5/64; H05K 5/0247
USPC 348/836; 174/50.5

(57) ABSTRACT

According to one embodiment, a television receiver includes a housing, a display, a first conductor, a second conductor, and an electrically conductive bonding layer. The display is in the housing. The first conductor is in the housing. The second conductor is in the housing. The electrically conductive bonding layer is between the first conductor and the second conductor. The electrically conductive bonding layer includes a compressed portion configured to be compressed in a direction in which the first conductor, the electrically conductive bonding layer, and the second conductor are stacked.

### CROSS-REFERENCE TO RELATED APPLICATIONS

This application is based upon and claims the benefit of priority from Japanese Patent Application No. 2013-090682, filed Apr. 23, 2013, the entire contents of which are incorporated herein by reference.

### FIELD

Embodiments described herein relate generally to a television receiver and an electronic device.

### BACKGROUND

Conventionally, there is known an electronic device comprises a first conductor and a second conductor provided in a housing and electrically connected to each other via an electrically conductive member.

For such electronic device, it is preferred to achieve a configuration that allows the first conductor and the second conductor to be more readily conductive.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of one example of a television receiver as viewed a front side according to a first embodiment;

FIG. 2 is an exemplary perspective view of a portion inside a housing of one example of the television receiver as viewed from the front side, in the first embodiment;

FIG. 3 is an exemplary cross-sectional view taken along line of FIG. 2 in the first embodiment;

FIG. 4 is an exemplary enlarged view of part IV of FIG. 3 in the first embodiment;

FIG. 5 is an exemplary enlarged view of part V of FIG. 3 in the first embodiment;

FIG. 6 is an exemplary perspective view of one example of an electronic device as viewed from a front side according to a second embodiment;

FIG. 7 is an exemplary cross-sectional view taken along line VII-VII of FIG. 6 in the second embodiment;

FIG. 8 is an exemplary front view of a protrusion included in one example of an electronic device according to a first modification;

FIG. 9 is an exemplary cross-sectional view taken along line IX-IX of FIG. 8 in the first modification;

FIG. 10 is an exemplary front view of a protrusion included in one example of an electronic device according to a second modification;

FIG. 11 is an exemplary front view of a protrusion included in one example of an electronic device according to a third modification;

FIG. 12 is an exemplary front view of a protrusion included in one example of an electronic device according to a fourth modification;

FIG. 13 is an exemplary front view of a protrusion included in one example of an electronic device according to a fifth modification;

FIG. 14 is an exemplary front view of a protrusion included in one example of an electronic device according to a sixth modification;

FIG. 15 is an exemplary cross-sectional view taken along line XV-XV of FIG. 14 in the sixth modification;

FIG. 16 is an exemplary front view of a protrusion included in one example of an electronic device according to a seventh modification;

FIG. 17 is an exemplary front view of a protrusion included in one example of an electronic device according to an eighth modification;

FIG. 18 is an exemplary front view of a protrusion included in one example of an electronic device according to a ninth modification;

FIG. 19 is an exemplary front view of a protrusion included in one example of an electronic device according to a tenth modification;

FIG. 20 is an exemplary cross-sectional view taken along line XX-XX of FIG. 19 in the tenth modification;

FIG. 21 is an exemplary front view of a protrusion included in one example of an electronic device according to an eleventh modification; and

FIG. 22 is an exemplary cross-sectional view of a portion of one example of a television receiver according to a third embodiment.

### DETAILED DESCRIPTION

In general, according to one embodiment, a television receiver comprises a housing, a display, a first conductor, a second conductor, and an electrically conductive bonding layer. The display is in the housing. The first conductor is in the housing. The second conductor is in the housing. The electrically conductive bonding layer is between the first conductor and the second conductor. The electrically conductive bonding layer comprises a compressed portion configured to be compressed in a direction in which the first conductor, the electrically conductive bonding layer, and the second conductor are stacked.

A plurality of exemplary embodiments and modifications to be described below comprise similar elements. Those similar elements will hereunder be similarly designated and duplicated descriptions for those elements will be omitted.

In the embodiments, an electronic device will be exemplified as being configured as a television receiver or what-is-called a clamshell or notebook personal computer. This is, however, not the only possible arrangement. The electronic device in the embodiments may be configured as a type of electronic device (e.g., a smart TV, a portable telephone, a video display, and a TV telephone) comprising a first conductor, an electrically conductive bonding layer, and a second conductor housed inside a housing.

### First Embodiment

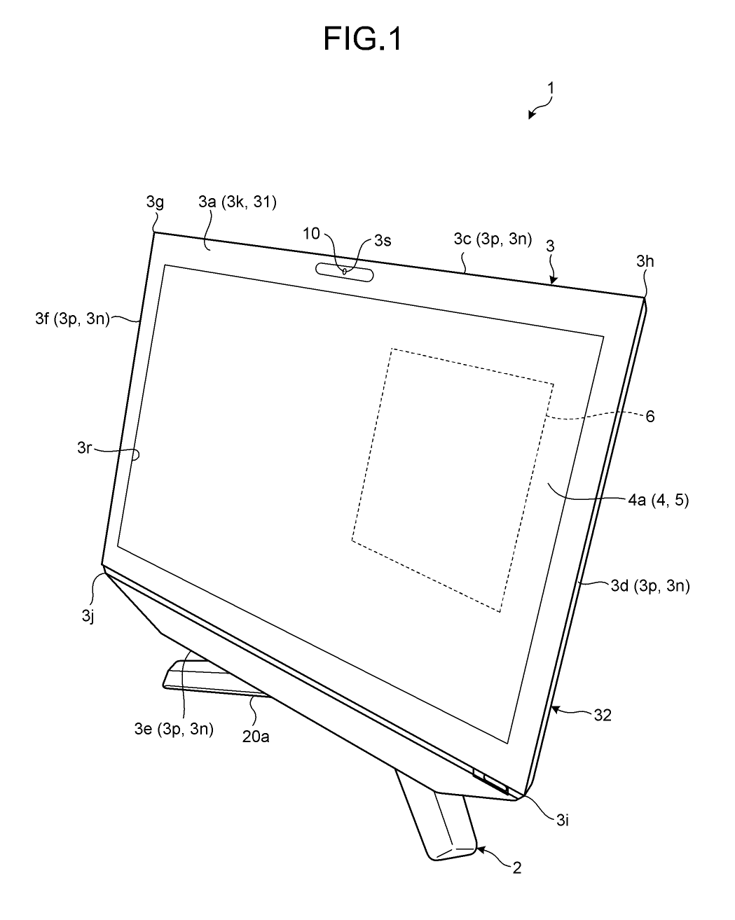

A television receiver 1 exemplified in a first embodiment illustrated in FIG. 1 comprises a support 2 and a housing 3. Specifically, the housing 3 (a first housing, a first portion, a first component) houses therein at least a portion of a display 4. The support 2 (a stand portion, abase, a support portion, a second housing, a second portion, another portion, another component) supports the housing 3. The support 2 has an area 20a (a bottom wall, a wall, an area, a portion, a foot) that, when the support 2 is placed on an external placement face, faces the external placement face.

As an example, in the first embodiment, the support 2 supports the housing 3 rotatably via a hinge (a connecting portion, a coupling portion, a rotational support portion, a hinge mechanism, a connecting mechanism, a coupling mechanism, a rotational support mechanism; not illustrated). As an example, in the first embodiment, the hinge permits tilting adjustments, varying an angle of a display screen 4a in a vertical direction. It is noted that the support 2 can support the housing 3 rotatably (e.g., a pivot and a swivel) in other directions.

As an example, in the first embodiment, the housing 3 of the television receiver 1 is formed into a quadrilateral (as an example, a rectangle in the first embodiment) in a front view and a back view. As an example, in the first embodiment, the housing 3 is formed into a flat rectangular parallelepiped being thin in a front-to-back direction. The housing 3 has a face 3a (a fore face, a front face, a first face, a first face portion) and a face 3b (a rear face, a back face, a second face, a second face portion) opposite thereto. Additionally, as illustrated in FIG. 1, the housing 3 has four ends 3c to 3f (side portions, edge portions) and four corners 3g to 3j (pointed portions, bent portions, end portions) in the front view. The ends 3c, 3e are exemplary long side portions. The ends 3d, 3f are exemplary short side portions.

In addition, the housing 3 has a wall 3k (a first portion, a plate, a frame, a fore wall portion, a front wall portion, a top wall portion) that has the face 3a and a wall 3m (a second portion, a plate, a rear wall portion, a back wall portion, a bottom wall portion; see FIG. 3) that has the face 3b. The walls 3k, 3m are each a quadrilateral (as an example, a rectangle in the first embodiment). Additionally, the housing 3 has four walls 3n (third portions, plates, side wall portions, end wall portions, vertical wall portions, extended portions), each having a face 3p (a side face, a peripheral face, a third face) extending across the wall 3k and the wall 3m. It is noted that the wall 3k has an as an example quadrilateral opening 3r. The wall 3k is thus shaped into a quadrilateral frame.

The housing 3 can be formed through combination of a plurality of components (divided bodies). As an example, in the first embodiment, the housing 3 comprises a first housing member 31 (a first portion, a fore-side member, a mask, a mask portion, a cover, a front cover, a cover portion, a first area) that comprises at least the wall 3k and a second housing member 32 (a second portion, a rear-side member, a base, a base portion, a bottom, a bottom portion, a cover, a rear cover, a cover portion, a second area) that comprises at least the wall 3m. The walls 3n are included in at least either one of the first housing member 31 and the second housing member 32 (e.g., the second housing member 32). The housing 3 may further comprise, for example, a third housing member (a third portion, an intermediate member, a separating member, a barrier member, a wall member, an intervening member, an inner plate, a middle plate, a middle frame, a third area; not illustrated) and a fourth housing member (a fourth portion, an intermediate member, a separating member, a barrier member, a wall member, an intervening member, a shielding member, a shield, a fourth area; not illustrated), in addition to the first housing member 31 and the second housing member 32. The third housing member and the fourth housing member are positioned between the first housing member 31 and the second housing member 32.

The housing 3 may be formed of, for example, a metal material or a synthetic resin material. The first housing member 31 and the second housing member 32 may be formed of a material having relatively low stiffness (material having stiffness lower than that of the third housing member or the fourth housing member; e.g., a synthetic resin material). The first housing member 31 or the second housing member 32 may be provided on an inner side of the housing 3 with a wall, for example, a rib (a protruding portion, a protruding wall portion; not illustrated). The wall tends to enhance stiffness of the housing 3.

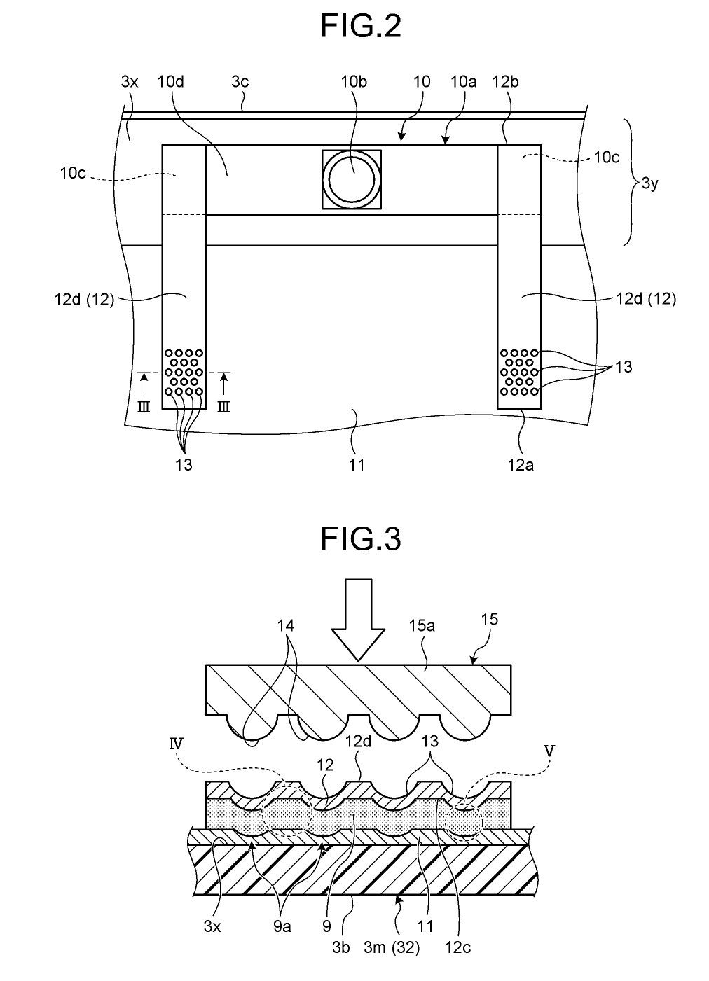

As an example, in the first embodiment, a connector (not illustrated) or an operating unit (not illustrated), for example, may be provided on, for example, the face 3b or the face 3p of the housing 3. The connector may, for example, be a power cable connector, a universal serial bus (USB) connector, a card connector, or an earphone or microphone connector. The operating unit may, for example, be a pushbutton, a push switch, a slide switch, a pointing device, or a dial. Additionally, as illustrated in FIG. 2, a camera module 10 (a camera, an imaging device) may be provided within the housing 3. Referring to FIG. 1, the camera module 10 is exposed through an opening 3s in the wall 3k of the housing 3.

As an example, in the first embodiment, as illustrated in FIG. 1, the display 4 (a display portion, a display, a panel) has the display screen 4a positioned on a face 3a side. The display screen 4a is exposed forwardly (outwardly) of the housing 3 via the opening 3r. A user can visually recognize the display screen 4a through the opening 3r from a forward side. The display 4 is formed into a quadrilateral (as an example, a rectangle in the first embodiment) in the front view. The display 4 is formed into a flat rectangular parallelepiped being thin in the front-to-back direction. The display 4 may, for example, be a liquid crystal display (LCD) or an organic electro-luminescent display (GELD).

As an example, in the first embodiment, an input operating panel 5 (e.g., a touch panel, a touch sensor, an operating face) is provided on the fore side (the front side, the wall 3k side) of the display 4. The input operating panel 5 is formed into a transparent, relatively thin quadrilateral covering the display screen 4a. An operator (e.g., the user) can perform an input operation by, for example, touching, pressing, or rubbing the input operating panel 5 with a finger or a part (e.g., a stylus, not illustrated), or moving a finger or a stylus near the input operating panel 5. Light emitted from the display screen 4a of the display 4 passes through the input operating panel 5 and travels ahead (outside) of the housing 3 by way of the opening 3r in the wall 3k. The input operating panel 5 may be configured as what-is-called an in-cell touch panel provided in the display 4. The input operating panel 5 is an exemplary input module.

As an example, in the first embodiment, as illustrated in FIG. 1, at least one substrate 6 (a circuit board, a control board, a main board, an electrical component, a first electrical component) is housed in the housing 3 at a rear side (the back side, the rear side, the wall 3m side, the side opposite the display screen 4a) of the display 4. The substrate 6 extends in parallel with the display 4. The substrate 6 is spaced away from, for example, the walls 3k, 3m, 3n; specifically, the substrate 6 is provided with a space (clearance) defined from each of the walls 3k, 3m, 3n.

As an example, in the first embodiment, a plurality of components (electrical components, electronic components; not illustrated) comprising a central processing unit (CPU), a graphic controller, a power supply circuit part, a platform controller hub (PCH), a memory slot connector, an LCD connector, an input/output (I/O) connector, a power supply coil, a device, and a connector can be mounted on the substrate 6. A control circuit may comprise, for example, a video signal processing circuit, a tuner, a high-definition multimedia interface (HDMI, registered trademark) signal processor, an audio video (AV) input terminal, a remote control signal receiver, a controller, a selector, an on-screen display interface, a storage (e.g., a read only memory (ROM), a random access memory (RAM), a hard disk drive (HDD), a solid state drive (SSD)), and an audio signal processing circuit. The control circuit controls, for example, the output of video (e.g., a moving image, a still image) on the display screen 4a of the display 4, audio output from a speaker (not illustrated), and illumination of a light emitting diode (LED, not illustrated). The display 4, the speaker, and the LED are each an exemplary output unit.

As an example, in the first embodiment, as illustrated in FIGS. 2 and 3, a first conductor 11 (a conductive layer, a conductive film) is provided in the housing 3. Specifically, the first conductor 11 is as an example formed into a film form (a thin sheet form). The first conductor 11 is positioned on a face 3x (an inner face, an inner side face) on a side opposite the face 3b on the wall 3m of the housing 3 and partially covers the face 3x. The first conductor 11 can be used as a ground electrode (a ground conductor, common ground) when the housing 3 is formed of, for example, an insulating synthetic resin material. The first conductor 11 may even be used as an electromagnetic shield that shields electromagnetic noise. The first conductor 11 can be configured as a metal member having electrical conductivity (e.g., aluminum foil, aluminum tape, a sputter layer).

As an example, in the first embodiment, as illustrated in FIG. 2, the camera module 10 is provided in the housing 3. Specifically, the camera module 10 comprises a substrate 10a and a camera unit 10b. The substrate 10a is formed into a long and narrow quadrilateral (rectangle) extending along the end 3c of the housing 3. Similarly to the first conductor 11, the substrate 10a is positioned on the face 3x (an inner face, an inner side face) of the housing 3. The substrate 10a is positioned in an area 3y not overlapping the first conductor 11 in a plan view (spaced away from the first conductor 11 on the end 3c side closer thereto relative to the first conductor 11). The camera unit 10b is provided at a substantially central portion in a longitudinal direction of the substrate 10a (in a left-to-right direction in FIG. 2). A conductor 10c is provided at each of both ends in the longitudinal direction of the substrate 10a (in the left-to-right direction in FIG. 2). The conductors 10c can be used as ground electrodes. The conductors 10c are exposed on a face 10d (a front face, an upper face) of the substrate 10a.

As an example, in the first embodiment, as illustrated in FIGS. 2 and 3, a second conductor 12 (a conductive layer, a conductive film) is provided in the housing 3. The second conductor 12 electrically connects the first conductor 11 to the conductor 10c of the substrate 10a. Noise may occur from a possible difference in electrical potential between the first conductor 11 (the ground electrode of the housing 3) and the conductor 10c of the substrate 10a (the ground electrode of the camera module 10). In this respect, in the first embodiment, as an example the second conductor 12 can suppress a potential difference between the ground electrodes, and suppress noise that occurs based on the potential difference. The second conductor 12 is formed into a long and narrow quadrilateral (a rectangle, a belt form, a strip form) extending in a direction intersecting with the longitudinal direction of the substrate 10a (the direction in which the end 3c extends, in the left-to-right direction in FIG. 2) (as an example in an orthogonal direction in the first embodiment). The second conductor 12 has a first end 12a (the end at the lower side in FIG. 2) overlapping, and electrically connected to, the first conductor 11. The second conductor 12 has a second end 12b (the end at the upper side in FIG. 2) overlapping, and electrically connected to, the conductor 10c of the substrate 10a. In addition, the second conductor 12 is associated with each of the conductors 10c of the substrate 10a. Specifically, in the first embodiment, a plurality of second conductors 12 (as an example, two in the first embodiment) are spaced apart from each other in the longitudinal direction of the substrate 10a (in the left-to-right direction in FIG. 2). The second conductor 12 can be configured, similarly to the first conductor 11, as a metal member having electrical conductivity (e.g., aluminum foil, aluminum tape).

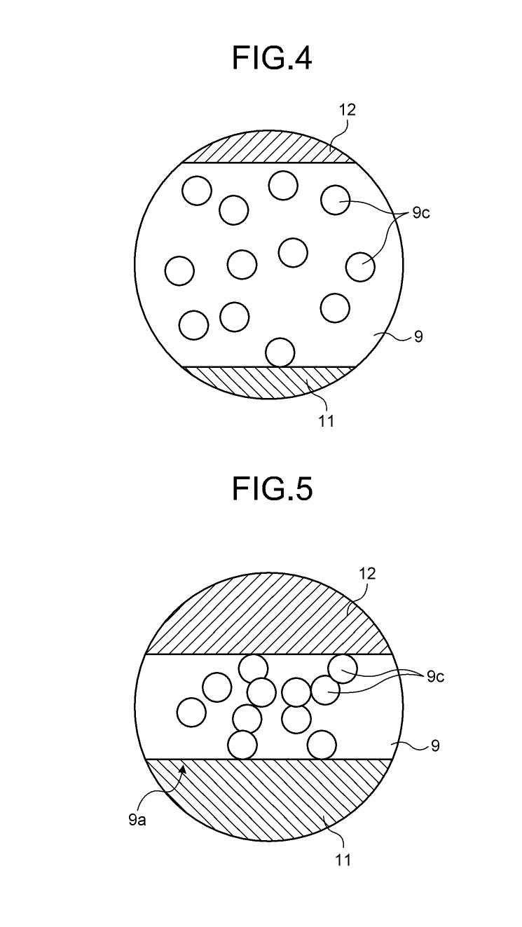

As an example, in the first embodiment, an electrically conductive bonding layer 9 (electrically conductive double-sided tape) is positioned between the first conductor 11 and the second conductor 12. As an example, in the first embodiment, the electrically conductive bonding layer 9 is formed into a long and narrow quadrilateral (a rectangle, a belt form, a strip form) extending in the direction intersecting the longitudinal direction of the substrate 10a (as an example in an orthogonal direction in the first embodiment; in the vertical direction in FIG. 2). The electrically conductive bonding layer 9 bonds the first conductor 11 to the second conductor 12. Additionally, the electrically conductive bonding layer 9 contains therein electrically conductive fillers 9c (e.g., metal particles, see FIG. 4). The first conductor 11 and the second conductor 12 conduct each other through the electrically conductive fillers 9c.

As an example, in the first embodiment, the electrically conductive bonding layer 9 comprises compressed portions 9a (collapsed portions, thin-walled portions). The compressed portions 9a are compressed in a direction in which the first conductor 11, the electrically conductive bonding layer 9, and the second conductor 12 are stacked one on top of another (a stacking direction, in a thickness direction of the housing 3 (wall 3m); in the vertical direction in FIG. 3). In addition, as an example, in the first embodiment, the compressed portions 9a are formed in the electrically conductive bonding layer 9 by using a jig 15 (a pressing member) having a plurality of protrusions 14 (projections, protuberances, protruding portions). Specifically, a main body 15a of the jig 15 is pressed in a direction of the arrow (downward direction) in FIG. 3, which causes the first conductor 11, the electrically conductive bonding layer 9, and the second conductor 12 to be sandwiched between the protrusions 14 and the wall 3m of the housing 3 (a second member) to thereby form the compressed portions 9a. As illustrated in FIG. 5, a thickness in the stacking direction of the electrically conductive bonding layer 9 is narrowed at the compressed portions 9a. Thus, at the compressed portions 9a, the electrically conductive fillers 9c are densely populated and tend to contact each other, as compared with portions other than the compressed portions 9a (non-compressed portions, general portions; see FIG. 4). Specifically, as an example, in the first embodiment, the compressed portions 9a in the electrically conductive bonding layer 9 allow electrical conductivity between the first conductor 11 and the second conductor 12 to be increased more easily.

As an example, in the first embodiment, the first conductor 11 or the second conductor 12 (the second conductor 12 in the example illustrated in FIG. 3) has recesses 13 (groove portions, hole portions, opening portions) formed on a face 12d (an upper face) opposite a face 12c (a lower face) on the electrically conductive bonding layer 9 side. Further, as an example, in the first embodiment, the compressed portions 9a are provided to the electrically conductive bonding layer 9 at positions corresponding to positions of the recesses 13. Thus, as an example, in the first embodiment, the recesses 13 provided in the second conductor 12 allow the compressed portions 9a to be more easily formed in the electrically conductive bonding layer 9.

As an example, the first embodiment uses the jig 15 (a first member, a pressing member) having the protrusions 14 that fit in the recesses 13. Thus, as an example, in the first embodiment, the protrusions 14 of the jig 15 allow the compressed portions 9a to be more easily formed in the electrically conductive bonding layer 9.

As an example, in the first embodiment, the electrically conductive bonding layer 9 has the compressed portions 9a. As an example, in the first embodiment, this tends to increase the number of conductive portions made by the compressed portions 9a. Thus, as an example, in the first embodiment, the electrical conductivity between the first conductor 11 and the second conductor 12 tends to increase.

As an example, in the first embodiment, referring to FIG. 2, the compressed portions 9a (and the recesses 13) are arranged in a zigzag pattern. Thus, as an example, in the first embodiment, density of the recesses 13 (the compressed portions 9a) tends to increase. Thus, as an example, in the first embodiment, the electrical conductivity between the first conductor 11 and the second conductor 12 tends to increase even more efficiently.

As an example, in the first embodiment, the protrusions 14 protrude hemispherically from the main body 15a of the jig 15 as illustrated in FIG. 3. Thus, as an example, in the first embodiment, the electrically conductive bonding layer 9 can be prevented from being damaged, as compared with protrusions having pointed ends.

As an example, in the first embodiment, the recesses 13 (the compressed portions 9a) are provided only in portions in which the first conductor 11 and the second conductor 12 overlap each other in a plan view. The recesses 13 (the compressed portions 9a) may nonetheless be provided also in portions in which the second conductor 12 and the conductors 10c of the substrate 10a overlap each other.

### Second Embodiment

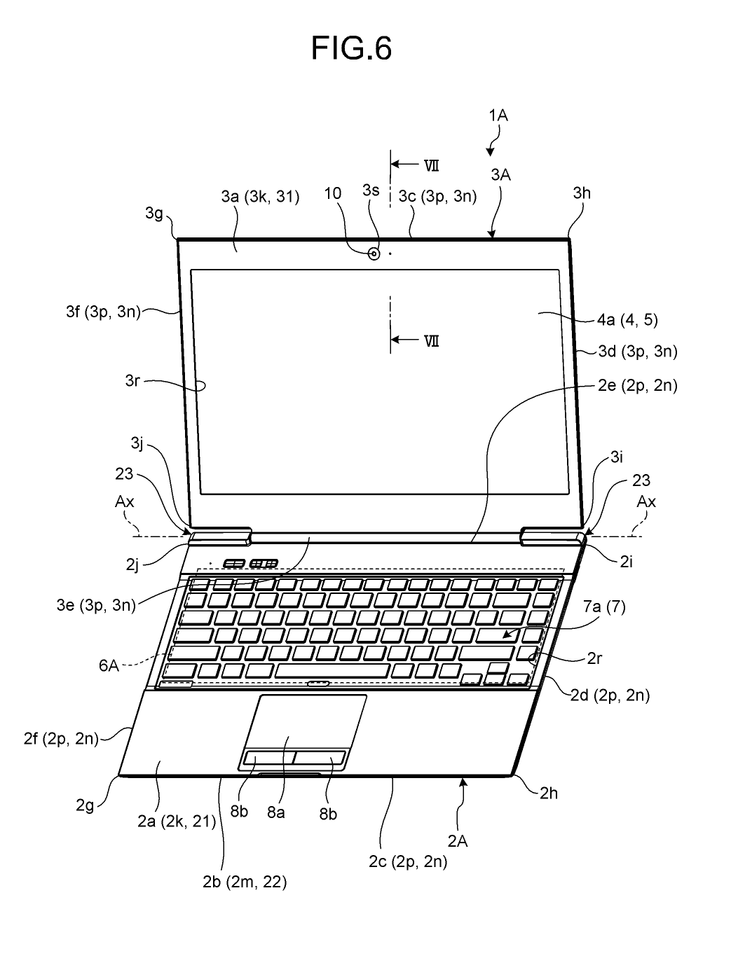

An electronic device LA exemplified in a second embodiment illustrated in FIG. 6 comprises a first housing 3A and a second housing 2A. Specifically, the first housing 3A (a first portion, a housing) houses therein at least a portion of a display 4. The second housing 2A houses therein a substrate 6A. A keyboard 7 (an input operating portion, a first input operating portion, an input receiving portion, an input portion), a pointing device 8a (an input operating portion, a second input operating portion, an input receiving portion, an input portion), and a click button 8b (an input operating portion, a third input operating portion, an input receiving portion, an input portion), for example, are provided on the second housing 2A.

The first housing 3A and the second housing 2A are rotatably connected to each other by a hinge 23 (a connecting portion, a coupling portion, a rotational support portion, a hinge mechanism, a connecting mechanism, a coupling mechanism, a rotational support mechanism). The first housing 3A and the second housing 2A are rotatably connected by the hinge 23 between at least a deployed position (see FIG. 6) and a folded position (not illustrated). Specifically, in the second embodiment, the hinge 23 rotatably connects the first housing 3A and the second housing 2A about a rotational axis Ax. The display 4 has a display screen 4a exposed through an opening 3r in a face 3a (a fore face, a front face, a first face, a first face portion) of the first housing 3A. In addition, the keyboard 7, the pointing device 8a, the click button 8b, and the like are exposed on a face 2a (an upper face, a front face, a first face, a first face portion) of the second housing 2A. In the folded position, the face 3a of the first housing 3A and the face 2a of the second housing 2A overlap each other and the display screen 4a, the keyboard 7, the pointing device 8a, the click button 8b, and the like are hidden by the first housing 3A and the second housing 2A. In the deployed position, the face 3a of the first housing 3A and the face 2a of the second housing 2A are exposed, thus allowing the display screen 4a, the keyboard 7, the pointing device 8a, the click button 8b, and the like to be used (visually recognizable or operable).

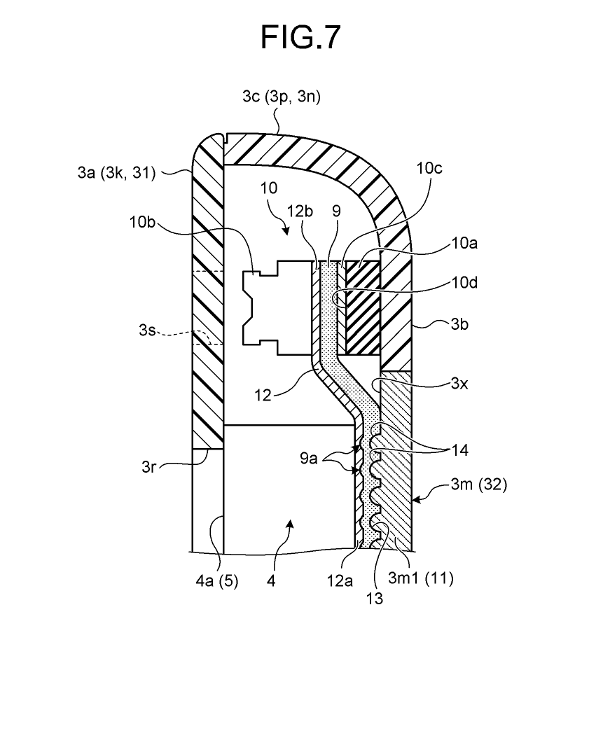

As an example, in the second embodiment, the first housing 3A is formed into a quadrilateral (as an example, a rectangle in the second embodiment) in a front view and a back view. As an example, in the second embodiment, the first housing 3A is formed into a flat rectangular parallelepiped being thin in a front-to-back direction. As illustrated in FIGS. 6 and 7, the first housing 3A has a face 3a (a fore face, a front face, a first face, a first face portion) and a face 3b (a rear face, a back face, a second face, a second face portion) opposite thereto. Additionally, as illustrated in FIG. 6, the first housing 3A has four ends 3c to 3f (side portions, edge portions) and four corners 3g to 3j (pointed portions, bent portions, end portions) in the front view. The ends 3c, 3e are exemplary long side portions. The ends 3d, 3f are exemplary short side portions.

In addition, the first housing 3A has a wall 3k (a first portion, a plate, a frame, a fore wall portion, a front wall portion, a top wall portion) that has the face 3a and a wall 3m (a second portion, a plate, a rear wall portion, a back wall portion, a bottom wall portion) that has the face 3b. The walls 3k, 3m are each a quadrilateral (as an example, a rectangle in the second embodiment). Additionally, the first housing 3A has four walls 3n (third portions, plates, side wall portions, end wall portions, vertical wall portions, extended portions), each having a face 3p (a side face, a peripheral face, a third face) extending across the wall 3k and the wall 3m. It is noted that the wall 3k has an as an example quadrilateral opening 3r. The wall 3k is thus shaped into a quadrilateral frame.

The first housing 3A can be formed through combination of a plurality of components (divided bodies). As an example, in the second embodiment, the first housing 3A comprises a first housing member 31 (a first portion, a fore-side member, a mask, a mask portion, a cover, a front cover, a cover portion, a first area) that comprises at least the wall 3k and a second housing member 32 (a second portion, a rear-side member, a base, a base portion, a bottom, a bottom portion, a cover, a rear cover, a cover portion, a second area) that comprises at least the wall 3m. The walls 3n are included in at least either one of the first housing member 31 and the second housing member 32 (e.g., the second housing member 32). The first housing 3A may further comprise, for example, a third housing member (a third portion, an intermediate member, a separating member, a barrier member, a wall member, an intervening member, an inner plate, a middle plate, a middle frame, a third area; not illustrated) and a fourth housing member (a fourth portion, an intermediate member, a separating member, a barrier member, a wall member, an intervening member, a shielding member, a shield, a fourth area; not illustrated), in addition to the first housing member 31 and the second housing member 32. The third housing member and the fourth housing member are positioned between the first housing member 31 and the second housing member 32.

The first housing 3A may be formed of, for example, a metal material or a synthetic resin material. The first housing member 31 and the second housing member 32 may be formed of a material having relatively low stiffness (material having stiffness lower than that of the third housing member or the fourth housing member, e.g., a synthetic resin material or a metal material). The first housing member 31 or the second housing member 32 may be provided on an inner side of the first housing 3A with a wall, for example, a rib (a protruding portion, a protruding wall portion; not illustrated). The wall tends to enhance stiffness of the first housing 3A.

As an example, in the second embodiment, as illustrated in FIGS. 6 and 7, a camera module 10 (a camera, an imaging device) may be provided within the first housing 3A. The camera module 10 is exposed through an opening 3s in the wall 3k of the first housing 3A. It is noted that a connector or an operating module, for example, may be provided on the face 3p of the first housing 3A.

As an example, in the second embodiment, as illustrated in FIG. 6, the display 4 (a display portion, a display, a panel) has the display screen 4a positioned on the face 3a side. The display screen 4a is exposed forwardly (outwardly) of the first housing 3A via the opening 3r. A user can visually recognize the display screen 4a through the opening 3r from a forward side. The display 4 is formed into a quadrilateral (as an example, a rectangle in the second embodiment) in the front view. The display 4 is formed into a flat rectangular parallelepiped being thin in the front-to-back direction. The display 4 may, for example, be a liquid crystal display (LCD) or an organic electro-luminescent display (GELD).

As an example, in the second embodiment, an input operating panel 5 (e.g., a touch panel, a touch sensor, an operating face) is provided on the fore side (the front side, the wall 3k side) of the display 4. The input operating panel 5 is formed into a transparent, relatively thin quadrilateral covering the display screen 4a. An operator (e.g., the user) can perform an input operation by, for example, touching, pressing, or rubbing the input operating panel 5 with a finger or a part (e.g., a stylus; not illustrated), or moving a finger or a stylus near the input operating panel 5. Light emitted from the display screen 4a of the display 4 passes through the input operating panel 5 and travels ahead (outside) of the first housing 3A by way of the opening 3r in the wall 3k. The input operating panel 5 may be configured as what-is-called an in-cell touch panel provided in the display 4. The input operating panel 5 is an exemplary input unit.

As an example, in the second embodiment, the second housing 2A is formed into a quadrilateral (as an example, a rectangle in the second embodiment) in a front view and a back view. As an example, in the second embodiment, the second housing 2A is formed into a flat rectangular parallelepiped being thin in a front-to-back direction. The second housing 2A has a face 2a (an upper face, a front face, a first face, a first face portion) and a face 2b (a lower face, a back face, a second face, a second face portion) opposite thereto. Additionally, as illustrated in FIG. 6, the second housing 2A has four ends 2c to 2f (side portions, edge portions) and four corners 2g to 2j (pointed portions, bent portions, end portions) in the front view. The ends 2c, 2e are exemplary long side portions. The ends 2d, 2f are exemplary short side portions.

In addition, the second housing 2A has a wall 2k (a first portion, a plate, a frame, a fore wall portion, a front wall portion, a top wall portion) that has the face 2a and a wall 2m (a second portion, a plate, a rear wall portion, a back wall portion, a bottom wall portion) that has the face 2b. The walls 2k, 2m are each a quadrilateral (as an example, a rectangle in the second embodiment). Additionally, the second housing 2A has four walls 2n (third portions, plates, side wall portions, end wall portions, vertical wall portions, extended portions), each having a face 2p (a side face, a peripheral face, a third face) extending across the wall 2k and the wall 2m. It is noted that the wall 2k has an as an example quadrilateral opening 2r. The wall 2k is thus shaped into a quadrilateral frame.

The second housing 2A can be formed through combination of a plurality of parts (divided elements). As an example, in the second embodiment, the second housing 2A comprises a first housing member 21 (a first portion, a fore-side member, a mask, a mask portion, a cover, a front cover, a cover portion, a first area) that comprises at least the wall 2k and a second housing member 22 (a second portion, a rear-side member, a base, a base portion, a bottom, a bottom portion, a cover, a rear cover, a cover portion, a second area) that comprises at least the wall 2m. The walls 2n are included in at least either one of the first housing member 21 and the second housing member 22 (e.g., the second housing member 22). The second housing 2A may further comprise, for example, a third housing member (a third portion, an intermediate member, a separating member, a barrier member, a wall member, an intervening member, an inner plate, a middle plate, a middle frame, a third area; not illustrated) and a fourth housing member (a fourth portion, an intermediate member, a separating member, a barrier member, a wall member, an intervening member, a shielding member, a shield, a fourth area; not illustrated), in addition to the first housing member 21 and the second housing member 22. The third housing member and the fourth housing member are positioned between the first housing member 21 and the second housing member 22.

The second housing 2A may be formed of, for example, a metal material or a synthetic resin material. The first housing member 21 and the second housing member 22 may be formed of a material having relatively low stiffness (material having stiffness lower than that of the third housing member or the fourth housing member; e.g., a synthetic resin material). The first housing member 21 or the second housing member 22 may be provided on an inner side of the second housing 2A with a wall, for example, a rib (a protruding portion, a protruding wall portion; not illustrated). The wall tends to enhance stiffness of the second housing 2A.

As an example, in the second embodiment, a connector (not illustrated), for example, may be provided on, for example, the face 2p of the second housing 2A. The connector may, for example, be a power cable connector, a universal serial bus (USB) connector, a card connector, or an earphone or microphone connector. It is noted that a connector or an operating unit may be provided on the face 2a of the second housing 2A.

As an example, in the second embodiment, as illustrated in FIG. 6, the keyboard 7 has an operating face 7a (a face, an upper face). The operating face 7a is exposed forwardly (outwardly) of the second housing 2A via the opening 2r. On the face 2a, the keyboard 7 is positioned on a side close to the end 2e, while the pointing device 8a and the click button 8b are positioned on a side close to the end 2c opposite to the end 2e. The end 2e is positioned on the rear side in a depth direction (front-to-back direction) and the end 2c is positioned on the front side in the depth direction.

As an example, in the second embodiment, at least one substrate 6A (a circuit board, a control board, a main board, an electrical component, a first electrical component) is housed inside the second housing 2A on a rear side (the back side, the rear side, the wall 2m side, the side opposite the operating face 7a) of the keyboard 7. The substrate 6A extends in parallel with the keyboard 7. The substrate 6A is spaced away from, for example, the walls 2k, 2m, 2n; specifically, the substrate 6A is provided with a space (clearance) defined from each of the walls 2k, 2m, 2n.

As an example, in the second embodiment, a plurality of components (electrical components, electronic components; not illustrated) comprising a central processing unit (CPU), a graphic controller, a power supply circuit part, a platform controller hub (PCH), a memory slot connector, a LCD connector, an input/output (I/O) connector, a power supply coil, a device, and a connector can be mounted on the substrate 6A. A control circuit may comprise, for example, a video signal processing circuit, a tuner, a high-definition multimedia interface (HDMI, registered trademark) signal processor, an audio video (AV) input terminal, a remote control signal receiver, a controller, a selector, an on-screen display interface, a storage (e.g., a read only memory (ROM), a random access memory (RAM), a hard disk drive (HDD), a solid state drive (SSD)), and an audio signal processing circuit. The control circuit controls, for example, the output of video (e.g., a moving image, a still image) on the display screen 4a of the display 4, audio output from a speaker (not illustrated), and illumination of a light emitting diode (LED, not illustrated). The display 4, the speaker, and the LED are each an exemplary output unit.

As an example, in the second embodiment, as illustrated in FIG. 7, at least a portion of the wall 3m (the second housing member 32) of the first housing 3A is formed of a metal material. Specifically, as an example, in the second embodiment, a portion 3m1 formed of a metal material of the wall 3m constitutes a first conductor 11. The first conductor 11 can be used as a ground electrode (a ground portion, common ground). The first conductor 11 may even be used as an electromagnetic shield that shields electromagnetic noise.

As an example, in the second embodiment, as illustrated in FIG. 7, the camera module 10 similar to that in the first embodiment is provided inside the first housing 3A (see FIG. 2). Specifically, the camera module 10 comprises a substrate 10a and a camera unit 10b. The substrate 10a is formed into a long and narrow quadrilateral (rectangle) extending along the end 3c of the first housing 3A. The camera unit 10b is provided at a substantially central portion in a longitudinal direction of the substrate 10a (see FIG. 2). A conductor 10c is provided at each of both ends in the longitudinal direction of the substrate 10a (see FIG. 2). The conductors 10c can be used as ground electrodes. The conductors 10c are exposed on a face 10d (a front face, an upper face).

As an example, in the second embodiment, as illustrated in FIG. 7, a second conductor 12 (a conductive layer, a conductive film) is provided inside the first housing 3A. The second conductor 12 electrically connects the first conductor 11 to the conductor 10c of the substrate 10a. Noise may occur from a possible difference in electrical potential between the first conductor 11 (the ground electrode of the first housing 3A) and the conductor 10c of the substrate 10a (the ground electrode of the camera module 10). In this respect, in the second embodiment, as an example the second conductor 12 can suppress a potential difference between the ground electrodes, and suppress noise that occurs based on the potential difference. The second conductor 12 is formed into a long and narrow quadrilateral (a rectangle, a belt form, a strip form) extending in a direction intersecting with the longitudinal direction of the substrate 10a (the direction in which the end 3c extends, in the left-to-right direction in FIG. 2) (as an example in an orthogonal direction in the second embodiment). The second conductor 12 has a first end 12a (the end on the lower side in FIG. 2) overlapping, and electrically connected to, the first conductor 11. The second conductor 12 has a second end 12b (the end on the upper side in FIG. 2) overlapping, and electrically connected to, the conductor 10c of the substrate 10a. In addition, the second conductor 12 is associated with each of the conductors 10c of the substrate 10a. Specifically, in the second embodiment, a plurality of second conductors 12 (as an example, two in the second embodiment) are spaced apart from each other in the longitudinal direction of the substrate 10a. The second conductor 12 can be configured as a metal member having electrical conductivity (e.g., aluminum foil, aluminum tape).

As an example, in the second embodiment, an electrically conductive bonding layer 9 (electrically conductive double-sided tape) is positioned between the first conductor 11 and the second conductor 12. As an example, in the second embodiment, the electrically conductive bonding layer 9 is formed into a long and narrow quadrilateral (a rectangle, a belt form, a strip form) extending in the direction intersecting with the longitudinal direction of the substrate 10a (as an example in an orthogonal direction in the second embodiment). The electrically conductive bonding layer 9 bonds the first conductor 11 to the second conductor 12. Additionally, the electrically conductive bonding layer 9 contains therein electrically conductive fillers 9c (e.g., metal particles, see FIG. 4). The first conductor 11 and the second conductor 12 conduct each other through the electrically conductive fillers 9c.

As an example, also in the second embodiment, the electrically conductive bonding layer 9 comprises compressed portions 9a (collapsed portions, thin-walled portions). The compressed portions 9a are compressed in a direction in which the first conductor 11, the electrically conductive bonding layer 9, and the second conductor 12 are stacked one on top of another (a stacking direction, in a thickness direction of the housing 3A (wall 3m); in the left-to-right direction in FIG. 7). In addition, as an example, in the second embodiment, the wall 3m of the first housing 3A has a plurality of protrusions 14 (projections, protuberances, protruding portions). As an example, in the second embodiment, the electrically conductive bonding layer 9 and the second conductor 12 are sandwiched between the protrusions 14 provided on the wall 3m (a first member, the first conductor 11) of the first housing 3A and the display 4 (a second member), to thereby form the compressed portions 9a. As illustrated in FIG. 7, a thickness in the stacking direction of the electrically conductive bonding layer 9 is narrowed at the compressed portions 9a. Thus, at the compressed portions 9a, the electrically conductive fillers 9c are densely populated and tend to contact each other, as compared with portions other than the compressed portions 9a (non-compressed portions, general portions; see FIG. 4). Specifically, as an example, in the second embodiment, the compressed portions 9a in the electrically conductive bonding layer 9 allow electrical conductivity between the first conductor 11 and the second conductor 12 to be increased more easily.

As an example, in the second embodiment, as illustrated in FIG. 7, the electrically conductive bonding layer 9 has recesses 13 (groove portions, hole portions, opening portions, slits). Thus, as an example, in the second embodiment, the compressed portions 9a can be more easily formed in the electrically conductive bonding layer 9.

As an example, in the second embodiment, the protrusions 14 of the wall 3m (the first member) fit in the recesses 13. Thus, as an example, in the second embodiment, the wall 3m of the first housing 3A allows the compressed portions 9a to be formed more easily in the electrically conductive bonding layer 9.

As an example, the second embodiment comprises the display 4 (the second member) so as to sandwich at least the electrically conductive bonding layer 9 (in the example illustrated in FIG. 7, the electrically conductive bonding layer 9 and the second conductor 12) between the display 4 and the wall 3m (the first member) of the first housing 3A. Thus, as an example, in the second embodiment, the compressed portions 9a can be formed by using the display 4. Thus, as an example, the configuration can be made smaller in size as compared with a case in which a part different from the display 4 is used as the second member. Additionally, as an example, the compressed portions 9a can be more easily maintained.

As an example, also in the second embodiment, the electrically conductive bonding layer 9 has the compressed portions 9a. Specifically, as an example, in the second embodiment, the protrusions 14 of the wall 3m form the recesses 13 in the electrically conductive bonding layer 9. As an example, this tends to increase the number of conductive portions made by the compressed portions 9a. Thus, as an example, in the second embodiment, the electrical conductivity between the first conductor 11 and the second conductor 12 tends to increase.

As an example, also in the second embodiment, the compressed portions 9a (and the recesses 13) may be arranged in a zigzag pattern. Thus, as an example, in the second embodiment, density of the recesses 13 (the compressed portions 9a) tends to increase. Thus, as an example, in the second embodiment, the electrical conductivity between the first conductor 11 and the second conductor 12 tends to increase even more efficiently.

As an example, also in the second embodiment, the protrusions 14 protrude hemispherically from a face 3x (an inner face, an inner side face, a face on a side opposite the face 3b) of the wall 3m as illustrated in FIG. 7. Thus, as an example, in the second embodiment, the electrically conductive bonding layer 9 can be prevented from being damaged, as compared with protrusions having pointed ends.

In addition, as an example, in the second embodiment, the first conductor 11, which forms a portion of the wall 3m of the first housing 3A, may be provided on the face 3x (an inner face, an inner side face) of the wall 3m, separately from the wall 3m. In this case, the recesses 13 are provided in a face of the first conductor 11 on aside opposite the electrically conductive bonding layer 9. Further, the compressed portions 9a are provided at positions of the electrically conductive bonding layer 9 corresponding to the recesses 13. Additionally, the wall 3m (the first member) then has the protrusions 14 that fit in the recesses 13. Further, the first conductor 11, the electrically conductive bonding layer 9, and the second conductor 12 are sandwiched between the wall 3m (the first member) and the display 4 (the second member).

As an example, in the second embodiment, the compressed portions 9a are formed by the electrically conductive bonding layer 9 and the second conductor 12 being sandwiched between the wall 3m and the display 4. The compressed portions 9a may nonetheless be formed by a worker who presses the second conductor 12 against the protrusions 14 by hand or using a tool.

As an example, also in the second embodiment, the recesses 13 (the compressed portions 9a) are provided only in portions in which the first conductor 11 and the second conductor 12 overlap each other. The recesses 13 (the compressed portions 9a) may nonetheless be provided also in portions in which the second conductor 12 and the conductors 10c of the substrate 10a overlap each other.

### First Modification

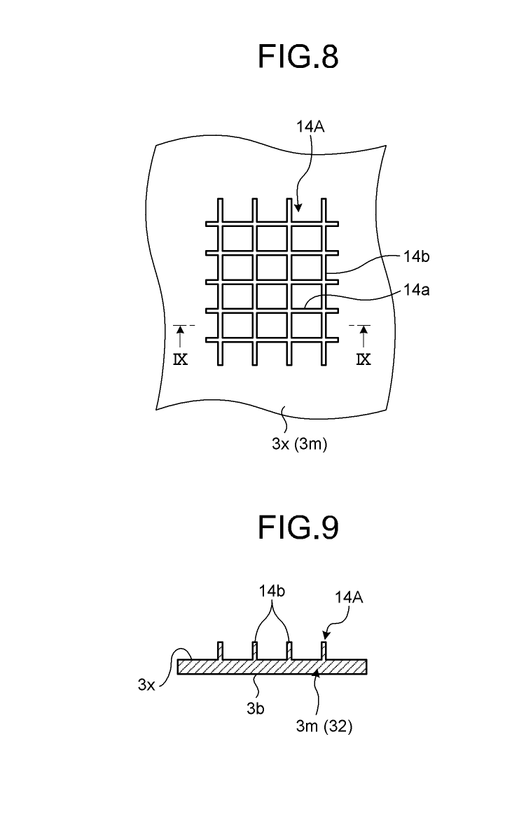

The modification depicted in FIGS. 8 and 9 has an arrangement similar to that of the electronic device 1A (or the television receiver 1) according to the second embodiment (or the first embodiment) described above. Thus, the first modification achieves results (effects) similar to those based on the arrangement similar to that of the above-described embodiments. Protrusions 14A illustrated in FIGS. 8 and 9 can be replaced with, for example, the protrusions 14 of the second embodiment (see FIG. 7).

It should be noted that, in the first modification, as an example, as illustrated in FIGS. 8 and 9, the protrusions 14A (wall portions, ribs, protruding portions) protrude from the face 3x (an inner face, an inner side face, a face on a side opposite the face 3b) of the wall 3m in a wall-like manner. In the first modification, as an example, the protrusions 14A comprise a plurality of first wall portions 14a (first ribs, crosswise wall portions) and a plurality of second wall portions 14b (second ribs, vertical wall portions), the first wall portions 14a and the second wall portions 14b intersecting with each other (in this modification, as an example, being orthogonal to each other). The first wall portions 14a and the second wall portions 14b are each formed into a rectangular sheet shape. The protrusions 14A comprise the first wall portions 14a extending in parallel with each other and the second wall portions 14b extending in parallel with each other, the first wall portions 14a and the second wall portions 14b being connected (integrated) to each other into a grid pattern (into a parallel-cross shape, into a ladder shape) in a plan view. Thus, in the first modification, as an example, the wall-like protrusions 14A provided on the wall 3m tend to enhance stiffness of the wall 3m. Also as an example, the wall-like protrusions 14A tend to increase the number of conductive portions made by the compressed portions 9a. Thus, as an example, in the first modification, the electrical conductivity between the first conductor 11 and the second conductor 12 tends to increase.

### Second Modification

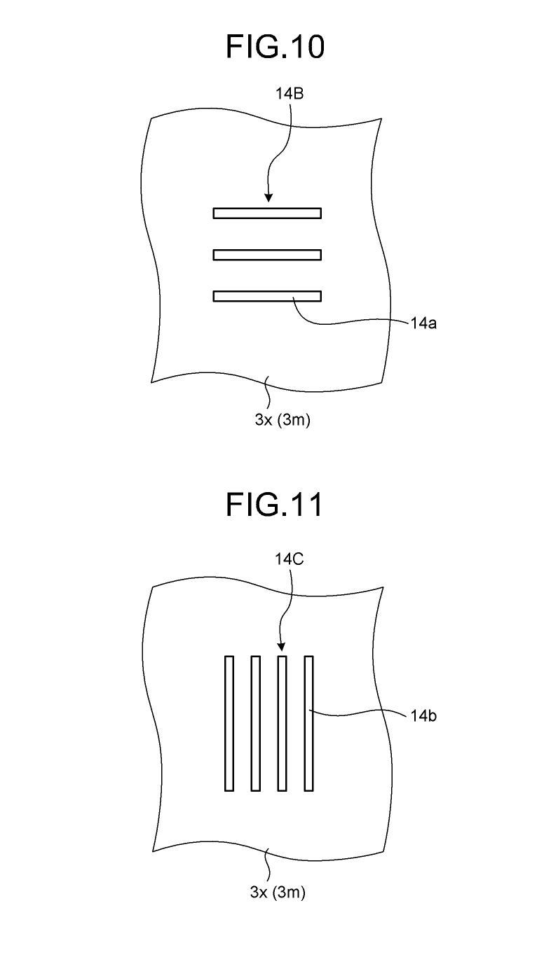

The modification depicted in FIG. 10 has an arrangement similar to that of the electronic device 1A (or the television receiver 1) according to the second embodiment (or the first embodiment) described above. Thus, the second modification achieves results (effects) similar to those based on the arrangement similar to that of the above-described embodiments. Protrusions 14B illustrated in FIG. 10 can be replaced with, for example, the protrusions 14 of the second embodiment (see FIG. 7).

It should be noted that, in the second modification, as an example, as illustrated in FIG. 10, the protrusions 14B (wall portions, ribs, protruding portions) protrude from the face 3x (an inner face, an inner side face, a face on a side opposite the face 3b) of the wall 3m in a wall-like manner. In the second modification, as an example, the protrusions 14B comprise a plurality of wall portions 14a (ribs, crosswise wall portions) extending in parallel with each other. The wall portions 14a are each formed into a rectangular sheet shape. Thus, in the second modification, as an example, the wall-like protrusions 14B provided on the wall 3m tend to enhance stiffness of the wall 3m. Also as an example, the wall-like protrusions 14B tend to increase the number of conductive portions made by the compressed portions 9a. Thus, as an example, in the second modification, the electrical conductivity between the first conductor 11 and the second conductor 12 tends to increase.

### Third Modification

The modification depicted in FIG. 11 has an arrangement similar to that of the electronic device 1A (or the television receiver 1) according to the second embodiment (or the first embodiment) described above. Thus, the third modification achieves results (effects) similar to those based on the arrangement similar to that of the above-described embodiments. Protrusions 14C illustrated in FIG. 11 can be replaced with, for example, the protrusions 14 of the second embodiment (see FIG. 7).

It should be noted that, in the third modification, as an example, as illustrated in FIG. 11, the protrusions 14C (wall portions, ribs, protruding portions) protrude from the face 3x (an inner face, an inner side face, a face on a side opposite the face 3b) of the wall 3m in a wall-like manner. In the third modification, as an example, the protrusions 14C comprise a plurality of wall portions 14b (ribs, vertical wall portions). The wall portions 14b are each formed into a rectangular sheet shape. The wall portions 14b, however, extend in a direction different from a direction in which the wall portions 14a of the second modification extend. Thus, in the third modification, as an example, the wall-like protrusions 14C provided on the wall 3m tend to enhance stiffness of the wall 3m. Also as an example, the wall-like protrusions 14C tend to increase the number of conductive portions made by the compressed portions 9a. Thus, as an example, in the third modification, the electrical conductivity between the first conductor 11 and the second conductor 12 tends to increase.

### Fourth Modification

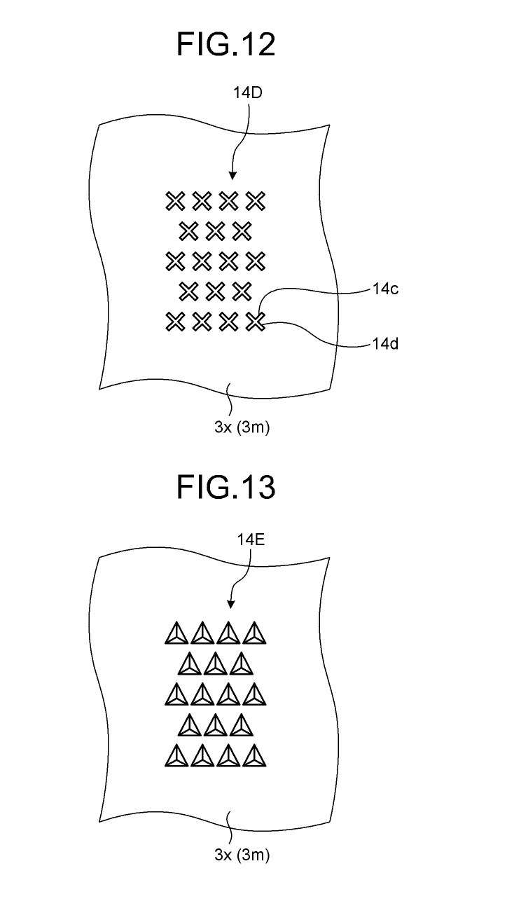

The modification depicted in FIG. 12 has an arrangement similar to that of the electronic device 1A (or the television receiver 1) according to the second embodiment (or the first embodiment) described above. Thus, the fourth modification achieves results (effects) similar to those based on the arrangement similar to that of the above-described embodiments. Protrusions 14D illustrated in FIG. 12 can be replaced with, for example, the protrusions 14 of the second embodiment (see FIG. 7).

It should be noted that, in the fourth modification, as an example, as illustrated in FIG. 12, the protrusions 14D (wall portions, ribs, protruding portions) protrude from the face 3x (an inner face, an inner side face, a face on a side opposite to the face 3b) of the wall 3m in a wall-like manner. In the fourth modification, as an example, the protrusions 14D each comprise a first wall portion 14c (a first rib) and a second wall portion 14d (a second rib), the first wall portion 14c and the second wall portion 14d intersecting with each other (in the second embodiment, as an example, being orthogonal to each other). The first wall portion 14c and the second wall portion 14d are each formed into a rectangular sheet shape. The protrusions 14D each comprise the first wall portion 14c and the second wall portion 14d being connected (integrated) to each other into an X-shape in a plan view. Additionally, as an example in the fourth modification, the protrusions 14D are provided on the face 3x of the wall 3m and arranged in a zigzag pattern in a plan view. Thus, in the fourth modification, as an example, the wall-like protrusions 14D provided on the wall 3m tend to enhance stiffness of the wall 3m. Also as an example, the protrusions 14D arranged in a zigzag pattern tend to increase density of the compressed portions 9a. Thus, as an example, in the fourth modification, the electrical conductivity between the first conductor 11 and the second conductor 12 tends to increase even further.

### Fifth Modification

The modification depicted in FIG. 13 has an arrangement similar to that of the electronic device 1A (or the television receiver 1) according to the second embodiment (or the first embodiment) described above. Thus, the fifth modification achieves results (effects) similar to those based on the arrangement similar to that of the above-described embodiments. Protrusions 14E illustrated in FIG. 13 can be replaced with, for example, the protrusions 14 of the second embodiment (see FIG. 7).

It should be noted that, in the fifth modification, as an example, as illustrated in FIG. 13, the protrusions 14E (protruding portions) protrude from the face 3x (an inner face, an inner side face, a face on a side opposite to the face 3b) of the wall 3m in a triangular pyramid-like manner. Additionally, as an example in the fifth modification, the protrusions 14E are provided on the face 3x of the wall 3m and arranged in a zigzag pattern in a plan view. The fifth modification also achieves results (effects) similar to those achieved by other embodiments and other modifications.

### Sixth Modification

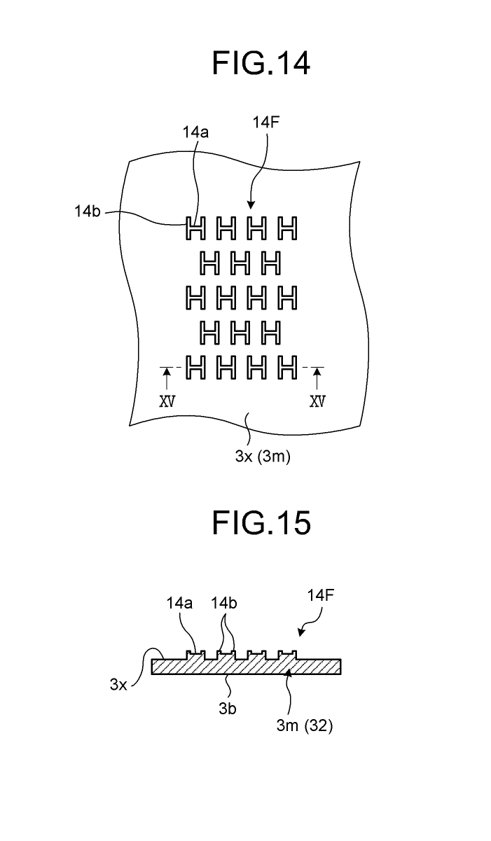

The modification depicted in FIGS. 14 and 15 has an arrangement similar to that of the electronic device 1A (or the television receiver 1) according to the second embodiment (or the first embodiment) described above. Thus, the sixth modification achieves results (effects) similar to those based on the arrangement similar to that of the above-described embodiments. Protrusions 14E illustrated in FIGS. 14 and 15 can be replaced with, for example, the protrusions 14 of the second embodiment (see FIG. 7).

It should be noted that, in the sixth modification, as an example, as illustrated in FIG. 14, protrusions 14F (wall portions, ribs, protruding portions) protrude from the face 3x (an inner face, an inner side face, a face on a side opposite to the face 3b) of the wall 3m in a wall-like manner. In the sixth modification, as an example, the protrusions 14F each comprise a first wall portion 14a (a first rib, a crosswise wall portion) and a pair of second wall portions 14b, 14b (second ribs, vertical wall portions), the first wall portion 14a and the second wall portions 14b, 14b intersecting with each other (in the second embodiment, as an example, being orthogonal to each other). The first wall portion 14a and the second wall portions 14b, 14b are each formed into a rectangular sheet shape. The protrusions 14F each comprise the first wall portion 14a and the second wall portions 14b, 14b being connected (integrated) to each other into an H-shape in a plan view. In addition, the protrusion height of the first wall portion 14a from a face 3X is a little smaller than the protrusion height of the second wall portion 14b from the face 3X. Additionally, as an example in the sixth modification, the protrusions 14F are provided on the face 3x of the wall 3m and arranged in a zigzag pattern in a plan view. Thus, in the sixth modification, as an example, the wall-like protrusions 14F provided on the wall 3m tend to enhance stiffness of the wall 3m. Also as an example, the protrusions 14F arranged in a zigzag pattern tend to increase density of the compressed portions 9a. Thus, as an example, in sixth modification, the electrical conductivity between the first conductor 11 and the second conductor 12 tends to increase even further.

### Seventh Modification

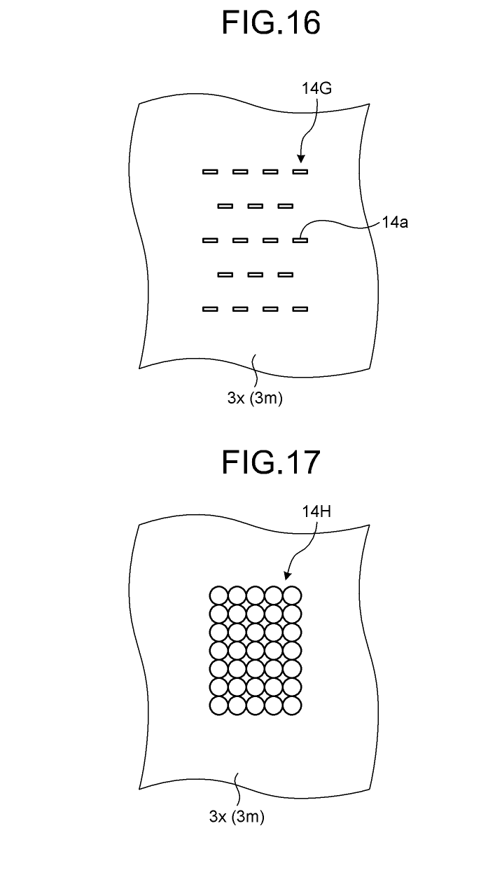

The modification depicted in FIG. 16 has an arrangement similar to that of the electronic device 1A (or the television receiver 1) according to the second embodiment (or the first embodiment) described above. Thus, the seventh modification achieves results (effects) similar to those based on the arrangement similar to that of the above-described embodiments. Protrusions 14G illustrated in FIG. 16 can be replaced with, for example, the protrusions 14 of the second embodiment (see FIG. 7).

It should be noted that, also in the seventh modification, as an example, as illustrated in FIG. 16, the protrusions 14G (wall portions, ribs, protruding portions) protrude from the face 3x (an inner face, an inner side face, a face on a side opposite the face 3b) of the wall 3m in a wall-like manner. As an example, in the seventh modification, the protrusions 14G each comprise wall portions 14a (ribs, crosswise wall portions). The wall portions 14a are each formed into a rectangular sheet shape. Additionally, the wall portions 14a are arranged in a zigzag pattern in a plan view, extending in parallel with each other. Thus, in the seventh modification, as an example, the protrusions 14G (wall portions 14a) arranged in a zigzag pattern tend to increase density of the compressed portions 9a. Thus, as an example, in the seventh modification, the electrical conductivity between the first conductor 11 and the second conductor 12 tends to increase even further.

### Eighth Modification

The modification depicted in FIG. 17 has an arrangement similar to that of the electronic device 1A (or the television receiver 1) according to the second embodiment (or the first embodiment) described above. Thus, the eighth modification achieves results (effects) similar to those based on the arrangement similar to that of the above-described embodiments. Protrusions 14H illustrated in FIG. 17 can be replaced with, for example, the protrusions 14 of the second embodiment (see FIG. 7).

It should be noted that, in the eighth modification, as an example, as illustrated in FIG. 17, the protrusions 14H (protruding portions) protrude hemispherically from the face 3x (an inner face, an inner side face, a face on a side opposite the face 3b) of the wall 3m. As an example, in the eighth modification, the protrusions 14H are densely populated on the face 3x of the wall 3m. The protrusions 14H are positioned such that adjacent ones contact each other. Thus, in the eighth modification, as an example, the densely positioned protrusions 14H tend to increase density of the compressed portions 9a. Thus, as an example, in the eighth modification, the electrical conductivity between the first conductor 11 and the second conductor 12 tends to increase even more efficiently.

### Ninth Modification

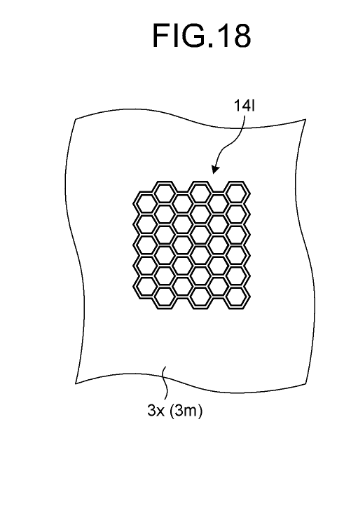

The modification depicted in FIG. 18 has an arrangement similar to that of the electronic device 1A (or the television receiver 1) according to the second embodiment (or the first embodiment) described above. Thus, the ninth modification achieves results (effects) similar to those based on the arrangement similar to that of the above-described embodiments. A protrusion 141 illustrated in FIG. 18 can be replaced with, for example, the protrusions 14 of the second embodiment (see FIG. 7).

It should be noted that, in the ninth modification, as an example, as illustrated in FIG. 18, the protrusion 141 (a wall portion, a rib, a protruding portion) protrudes from the face 3x (an inner face, an inner side face, a face on a side opposite to the face 3b) of the wall 3m in a wall-like manner. As an example, in the ninth modification, the protrusion 14I is formed into a honeycomb shape (a honeycomb shape, a honeycomb structure, a beehive-like manner, a hexagonal shape) in a plan view. Thus, in the ninth modification, as an example, the honeycomb protrusion 14I tends to enhance stiffness of the wall 3m. Also, as an example, the protrusion 141 tends to increase density of the compressed portions 9a. Thus, in the ninth modification, the electrical conductivity between the first conductor 11 and the second conductor 12 tends to increase even more efficiently.

### Tenth Modification

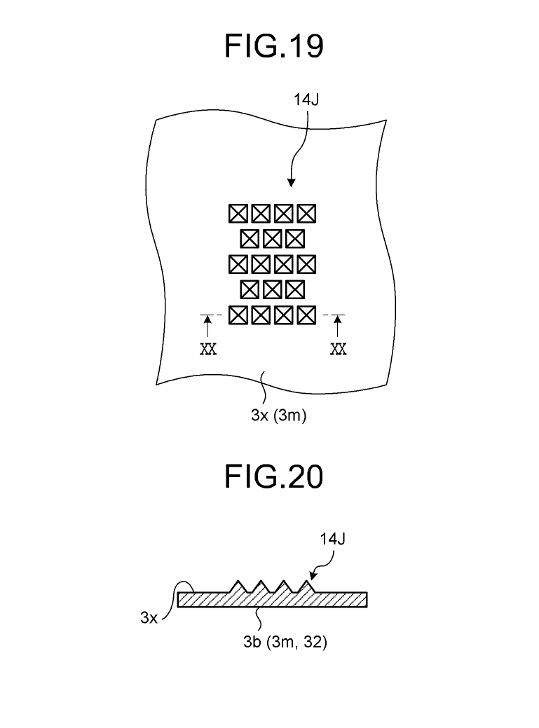

The modification depicted in FIGS. 19 and 20 has an arrangement similar to that of the electronic device 1A (or the television receiver 1) according to the second embodiment (or the first embodiment) described above. Thus, the tenth modification achieves results (effects) similar to those based on the arrangement similar to that of the above-described embodiments. Protrusions 14J illustrated in FIGS. 19 and 20 can be replaced with, for example, the protrusions 14 of the second embodiment (see FIG. 7).

It should be noted that, in the tenth modification, as an example, as illustrated in FIGS. 19 and 20, the protrusions 14J (protruding portions) protrude from the face 3x (an inner face, an inner side face, a face on a side opposite the face 3b) of the wall 3m in a quadrangular pyramid-like manner. Additionally, as an example in the tenth modification, the protrusions 14J are provided on the face 3x of the wall 3m and arranged in a zigzag pattern in a plan view. The tenth modification also achieves results (effects) similar to those achieved by other embodiments and other modifications.

### Eleventh Modification

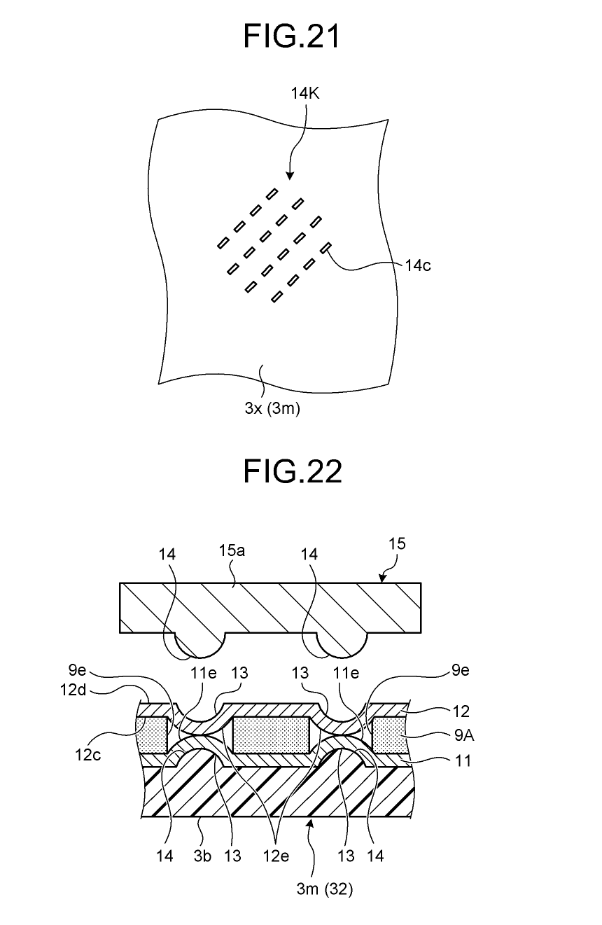

The modification depicted in FIG. 21 has an arrangement similar to that of the electronic device 1A (or the television receiver 1) according to the second embodiment (or the first embodiment) described above. Thus, the eleventh modification achieves results (effects) similar to those based on the arrangement similar to that of the above-described embodiments. Protrusions 14K illustrated in FIG. 21 can be replaced with, for example, the protrusions 14 of the second embodiment (see FIG. 7).

It should be noted that, in the eleventh modification, as an example, as illustrated in FIG. 21, the protrusions 14K (wall portions, ribs, protruding portions) protrude from the face 3x (an inner face, an inner side face, a face on a side opposite the face 3b) of the wall 3m in a wall-like manner. As an example, in the eleventh modification, the protrusions 14K comprise a plurality of wall portions 14c (ribs). The wall portions 14c are each formed into a rectangular sheet shape. Additionally, the wall portions 14c are arranged in a zigzag pattern in a plan view, extending in parallel with each other. Thus, in the eleventh modification, as an example, the protrusions 14K (wall portions 14C) arranged in a zigzag pattern tend to increase density of the compressed portions 9a. Thus, as an example, in the eleventh modification, the electrical conductivity between the first conductor 11 and the second conductor 12 tends to increase even further.

In each of the first through eleventh modifications described above, the protrusions 14 on the wall 3m according to the second embodiment are replaced by each of the protrusions 14A to 14K. Each of the protrusions 14A to 14K may nonetheless replace the protrusions 14 on the jig 15 according to the first embodiment. In addition, the protrusions 14, 14A to 14K may still be provided on a portion of the display 4 facing the second conductor 12.

### Third Embodiment

A third embodiment depicted in FIG. 22 has an arrangement similar to that of the television receiver 1 (or the electronic device 1A) according to the first embodiment (or the second embodiment) described above. Thus, the third embodiment also achieves results (effects) similar to those based on the arrangement similar to that of the above-described embodiments. A bonding layer 9A illustrated in FIG. 22 can be replaced with, for example, the electrically conductive bonding layer 9 of the first embodiment illustrated in FIG. 3.

It should be noted that, in the third embodiment, as an example, as illustrated in FIG. 22, the bonding layer 9A has openings 9e. In the third embodiment, as an example, the openings 9e in the bonding layer 9A are positioned between protrusions 14 of a wall 3m and protrusions 14 of a jig 15 and overlap in a thickness direction of the wall 3m (in the vertical direction of FIG. 22). A first conductor 11 and a second conductor 12 are sandwiched between (the protrusions 14 of) the wall 3m and (the protrusions 14 of) the jig 15. Thus, in the third embodiment, as an example, the first conductor 11 (a first conductor) has a protrusion 11e that protrudes toward the second conductor 12 (a second conductor) side in the opening 9e. Similarly, the second conductor 12 (a first conductor) has a protrusion 12e that protrudes toward the first conductor 11 (a second conductor) side in the opening 9e. In the third embodiment, as an example, (the protrusion 11e of) the first conductor 11 and (the protrusion 12e of) the second conductor 12 directly contact each other in the opening 9e and are electrically connected to each other. Thus, in the third embodiment, as an example, the electrical conductivity between the first conductor 11 and the second conductor 12 tends to increase even further.

In the third embodiment, as an example, the first conductor 11 and the second conductor 12 have the protrusions 11e, 12e, respectively. Alternatively, however, only either one of the first conductor 11 and the second conductor 12 may have the protrusion 11e (or 12e).

In the third embodiment, the bonding layer 9A has the openings 9e. The electrically conductive bonding layer 9 may, instead, have the openings 9e.

The third embodiment has exemplified the bonding layer 9A to replace the electrically conductive bonding layer 9 of the television receiver 1 according to the first embodiment described above. The bonding layer 9A may still replace the electrically conductive bonding layer 9 of the electronic device 1A according to the second embodiment described above. It is noted that, in the third embodiment, the bonding layer 9A may not necessarily have electrical conductivity; however, the bonding layer 9A may have electrical conductivity.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. In addition, part of elements may be exchanged among different embodiments and modifications. The specifications (including the structure, type, direction, shape, size, length, width, thickness, height, quantity, disposition, position, and material) of each element may be changed as appropriate for different embodiments.

What is claimed is:

1. A television receiver comprising:
a housing;
a display in the housing;
a first conductor in the housing;
a second conductor in the housing; and
an electrically conductive bonding layer between the first conductor and the second conductor, wherein
the electrically conductive bonding layer comprises a compressed portion configured to be compressed in a direction in which the first conductor, the electrically conductive bonding layer, and the second conductor are stacked.

2. The television receiver of claim 1, wherein
the first conductor or the second conductor comprises a recess formed on a face thereof opposite the electrically conductive bonding layer, and
the compressed portion of the electrically conductive bonding layer is configured to be at a position corresponding to where the recess is formed.

3. The television receiver of claim 2, further comprising a first member comprising a protrusion configured to fit in the recess.

4. The television receiver of claim 3, further comprising a second member, at least the electrically conductive bonding layer being sandwiched between the second member and the first member.

5. The television receiver of claim 1, wherein the electrically conductive bonding layer comprises a plurality of compressed portions.

6. The television receiver of claim 5, wherein the plurality of compressed portions are arranged in a zigzag pattern.

7. The television receiver of claim 3, wherein the protrusion is configured to protrude hemispherically.

8. The television receiver of claim 3, wherein the protrusion is configured to protrude in a wall-like manner.

9. A television receiver comprising:
a housing;
a display in the housing;
a first conductor in the housing;
a second conductor in the housing; and
a bonding layer between the first conductor and the second conductor, and comprising an opening, wherein
at least one of the first conductor and the second conductor comprises a protrusion configured to protrude toward other one of the first conductor and the second conductor in the opening, and the protrusion is configured to be in contact with and electrically connected to the other one of the first conductor and the second conductor.

10. An electronic device comprising:
a housing;
a first conductor in the housing;
a second conductor in the housing; and
an electrically conductive bonding layer between the first conductor and the second conductor, wherein
the electrically conductive bonding layer comprises a compressed portion configured to be compressed in a direction in which the first conductor, the electrically conductive bonding layer, and the second conductor are stacked.
